(19) United States
(12) Patent Application Publication
(10) Pub. No.: US 2026/0313835 A1
(43) Pub. Date: Oct. 8, 2026

(54) DATA CENTER PREFABRICATED MODULE, DATA CENTER PREFABRICATED UNIT AND MODULAR DATA CENTER

(71) Applicant: Beijing Fulllink Oreith Technology Co., Ltd., Beijing (CN)

(72) Inventors: Yifang LIU, Beijing (CN); Yuezheng MA, Beijing (CN)

(21) Appl. No.: 19/216,173

(22) Filed: May 22, 2025

(30) Foreign Application Priority Data
Apr. 3, 2025 (CN) 202510421051.X

(51) Int. Cl. H05K 7/20; H05K 7/14

(52) U.S. Cl. CPC H05K 7/20272; H05K 7/1491; H05K 7/1492; H05K 7/1495; H05K 7/20136; H05K 7/20745; H05K 7/2079

(57) ABSTRACT

Provided are a data center prefabricated module, a data center prefabricated unit and a modular data center. The data center prefabricated module includes an upper enclosure and a lower enclosure. The upper enclosure is internally provided with cable trays extending in a length direction of the upper enclosure, and an upper cold channel and an upper hot channel are respectively formed on both sides of the cable tray in a width direction. The upper cold channel communicates with the upper hot channel through a space above the cable tray, and an air conditioning terminal is arranged in the space above the cable tray. Multiple cabinets are sequentially arranged in the lower enclosure in a length direction. The upper enclosure is stacked on the lower enclosure, a lower cold channel communicates with the upper cold channel, and a lower hot channel communicates with the upper hot channel.

### CROSS-REFERENCE TO RELATED APPLICATION

This patent application claims the benefit and priority of Chinese Patent Application No. 202510421051.X, entitled "DATA CENTER PREFABRICATED MODULE, DATA CENTER PREFABRICATED UNIT AND MODULAR DATA CENTER" filed on Apr. 03, 2025, the disclosure of which is incorporated by reference herein in its entirety as part of the present application.

### TECHNICAL FIELD

The present disclosure relates to the technical field of data centers, and in particular to a data center prefabricated module, a data center prefabricated unit and a modular data center.

### BACKGROUND

With the full opening of digital economy and artificial intelligence as well as the supply of high-quality computing power and the circulation of high-efficiency data, the data center, as an important infrastructure in the information age, has become a key force for the rapid development of various industries in society. Artificial intelligence, cloud computing and big data technology are progressing with each passing day, the integration of traditional industries and emerging technologies is deepening, and the digital industry is booming. Data center computing power supply, as the core driving force, is reshaping the world economic map with new key productivity forms.

The traditional construction mode for the data center has the problems such as long construction period, low energy utilization rate, rapid technological upgrading, low management and operation efficiency and high construction investment, which all restrict the further development of computing power to some extent. To solve these problems, the data center, as the infrastructure of computing power output, urgently needs a brand-new construction mode to promote the development of computing power in a more efficient, economical and environmentally friendly way.

### SUMMARY

The embodiments aim to provide a data center prefabricated module, a data center prefabricated unit and a modular data center to solve the problems in the prior art, which are conducive to rapidly promoting the development of computing power.

To achieve the objective above, the present disclosure employs the following technical solutions.

The present disclosure provides a data center prefabricated module, including an upper enclosure and a lower enclosure. The upper enclosure is internally provided with cable trays extending in a length direction of the upper enclosure. An upper cold channel and an upper hot channel are respectively formed on both sides of each of the cable trays in a width direction. The upper cold channel communicates with the upper hot channel through a first space above each of the cable trays. An air conditioning terminal is arranged in the first space above each of the cable trays, and a pneumatic power source for driving gas to flow is arranged in the upper cold channel, the upper hot channel or the first space above each of the cable trays. Multiple cabinets are sequentially arranged in the lower enclosure in a length direction of the lower enclosure. The cabinets at least include a computing cabinet, a network cabinet, a distribution cabinet, a UPS (uninterrupted power supply) cabinet, a storage battery cabinet, a fire protection cabinet and a liquid cooling cabinet. A liquid cooling pipeline is arranged in a second space above the cabinet. The liquid cooling pipeline communicates with the computing cabinet as well as a liquid cooling channel in the network cabinet. First sealing plates are at least fixedly arranged on both sides of the second space above the cabinet in a width direction, respectively. The cabinet and the first sealing plates divide a remaining space of the lower enclosure into a lower cold channel and a lower hot channel. In an installation state, the upper enclosure is stacked on the lower enclosure, the lower cold channel communicates with the upper cold channel, and the lower hot channel communicates with the upper hot channel.

In some embodiments, a length and a width of the lower enclosure are same as a length and a width of the upper enclosure.

In some embodiments, each of four side surfaces of the upper enclosure and four side surfaces of the lower enclosure is provided with a fire roller shutter, and each of the upper enclosure and the lower enclosure is provided with a sliding door at least at one side surface in the length direction.

In some embodiments, the lower enclosure is internally provided with a partition which is arranged in a direction perpendicular to the length direction of the lower enclosure and which divides an internal space of the lower enclosure into a computer room and a support area. Multiple computing cabinets and network cabinets are arranged in the computer room. The distribution cabinet, the UPS cabinet, the storage battery cabinet, the fire protection cabinet and the liquid cooling cabinet are arranged in the support area.

In some embodiments, a grating is fixedly arranged at a bottom of the upper cold channel.

In some embodiments, a first top plate is fixedly arranged at a top of the upper enclosure. A first bottom plate is detachably arranged at a bottom of the upper enclosure. A second top plate is detachably arranged at a top of the lower enclosure. A second bottom plate is fixedly arranged at a bottom of the lower enclosure. A first upright posts are fixedly arranged inside each of the upper enclosure and the lower enclosure. Second upright posts are detachably arranged at four side edges of the upper enclosure and the lower enclosure, respectively.

The present disclosure further provides a data center prefabricated unit, including two data center prefabricated modules above. In an installation state, the two data center prefabricated modules are symmetrically arranged along a vertical plane parallel to the length direction of the upper enclosure.

The present disclosure further provides a modular data center, including multiple data center prefabricated units above, medium-voltage distribution boxes and cooling outdoor units.

In some embodiments, multiple data center prefabricated units are sequentially arranged in a width direction of a single data center prefabricated unit to form a data center prefabricated unit group.

In some embodiments, multiple of data center prefabricated unit groups are provided, which are sequentially arranged in a length direction of the single data center prefabricated unit. A corridor is arranged between two adjacent data center prefabricated unit groups of the multiple data center prefabricated unit groups.

Compared with the prior art, the embodiments have the following technical effects.

By adopting a fully prefabricated modular design, a brand-new power supply, distribution and cooling system is constructed, the rapid deployment of on-site assembled combination of a modular data center is achieved, a green and low-carbon innovative service platform for external transportation of computing power with rapid deployment, safety, high efficiency and wide adaptability is provided. Therefore, the development of the computing power can be rapidly promoted.

### BRIEF DESCRIPTION OF THE DRAWINGS

To describe the technical solutions of the embodiments of the present disclosure or in the prior art more clearly, the following briefly introduces the drawings required for describing the embodiments. Apparently, the drawings in the following description show merely some embodiments of the present disclosure, and those of ordinary skill in the art may still derive other drawings from these drawings without creative efforts.

FIG. 1 is a front view of a data center prefabricated unit according to the present disclosure;

FIG. 2 is a side view of the data center prefabricated unit according to the present disclosure;

FIG. 3 is a schematic diagram of the arrangement of various cabinets as well as arrangement positions of medium-voltage distribution boxes and cooling outdoor units in a modular data center according to the present disclosure.

List of the reference characters: 1 modular data center; 2 data center prefabricated unit; 3 medium voltage distribution box; 4 cooling outdoor unit; 5 upper enclosure; 6 lower enclosure; 7 fire roller shutter; 8 antistatic layer; 9 partition; 10 computer room; 11 support area; 12 computing cabinet; 13 network cabinet; 14 sliding door; 15 first sealing plate; 16 first distribution cabinet; 17 UPS cabinet; 18 storage battery cabinet; 19 second distribution cabinet; 20 fire protection cabinet; 21 liquid cooling cabinet; 22 cable tray; 23 upper cold channel; 24 second sealing plate; 25 network raceway; 26 weak current raceway; 27 heavy current raceway; 28 air conditioning terminal; 29 fan set; 30 corridor; 31 constant humidity unit; 32 fresh air unit; 33 second upright post; 34 air valve; 35 grating; 36 liquid cooling pipeline; 37 first upright post; 38 upper hot channel; 39 lower hot channel; and 40 lower cold channel.

### DETAILED DESCRIPTION OF THE EMBODIMENTS

The following clearly and completely describes the technical solutions in the embodiments of the present disclosure with reference to the drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts shall fall within the protection scope of the present disclosure.

In order to make the objectives, features and advantages of the present disclosure more clearly, the present disclosure is further described in detail below with reference to the embodiments.

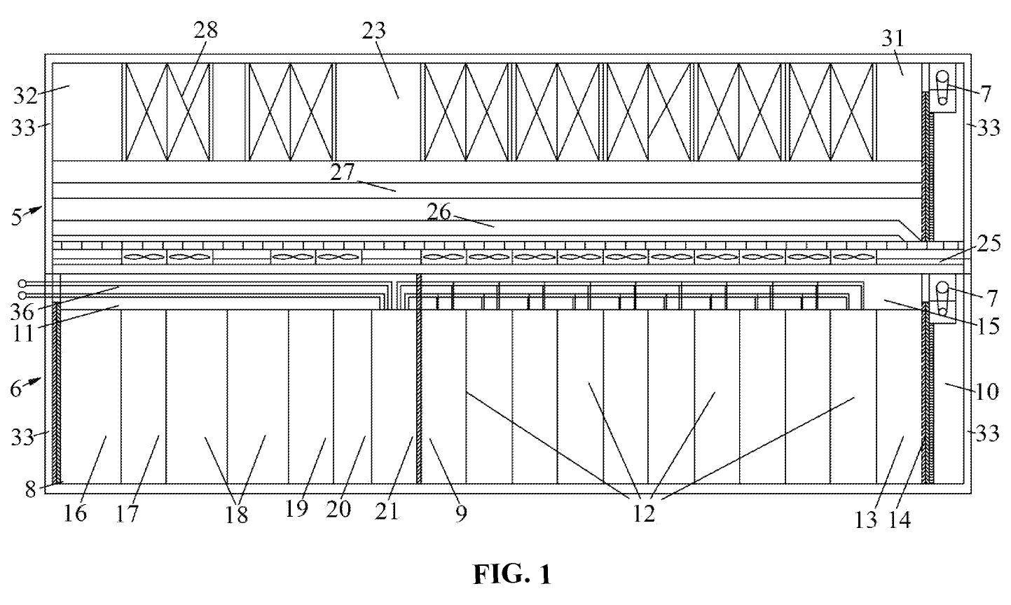

The embodiments of the present disclosure are further described below in detail with reference to FIGS. 1-3.

### Embodiment I

The present disclosure provides a data center prefabricated module, including an upper enclosure 5 and a lower enclosure 6. The upper enclosure 5 is internally provided with cable trays 22 extending in a length direction of the upper enclosure 5, an upper cold channel 23 and an upper hot channel 38 are respectively formed on both sides of the cable tray 22 in a width direction. The upper cold channel 23 communicates with the upper hot channel 38 through a space above the cable trays 22, and an air conditioning terminal 28 is arranged in the space above the cable trays 22, which may also be called an air conditioning cold end or an evaporator. A pneumatic power source, which may be a fan or a gas pump, for driving a gas to flow is arranged in the upper cold channel 23, the upper hot channel 38 or the space above the cable trays 22. Multiple cabinets are sequentially arranged in the lower enclosure 6 in a length direction of the lower enclosure 6, the cabinets at least include a computing cabinet 12, a network cabinet 13, distribution cabinets (a first distribution cabinet 16 and a second distribution cabinet 19 in FIG. 1), a UPS cabinet 17, a storage battery cabinet 18, a fire protection cabinet 20 and a liquid cooling cabinet 21. A liquid cooling pipeline 36 is arranged in a space above the cabinet, the liquid cooling pipeline 36 is connected with the liquid cooling cabinet 21, and the liquid cooling pipeline 36 communicates with the computing cabinet 12 and a liquid cooling channel in the network cabinet 13. First sealing plates 15 are at least fixedly arranged on both sides of the space above the cabinet in a width direction, and the cabinet and the first sealing plates 15 are configured to divide the remaining space of the lower enclosure 6 into a lower cold channel 40 and a lower hot channel 23. In an installation state, the upper enclosure 5 is stacked on the lower enclosure 6, the lower cold channel 40 communicates with the upper cold channel 23, and the lower hot channel 39 communicates with the upper hot channel 38. It may be understood that before installing the data center prefabricated module, the positional relationship between the upper enclosure 5 and the lower enclosure 6 is not limited.

The prefabricated modules in the present disclosure can be prefabricated in the factory and transported to a corresponding site for installation, and can be put into use after installation. Therefore, by adopting a fully prefabricated modular design, a brand-new power supply, distribution and cooling system is constructed, the rapid deployment of on-site assembled combination of a modular data center 1 is achieved, a green and low-carbon innovative service platform for external transportation of computing power with rapid deployment, safety, high efficiency and wide adaptability is provided.

It should be noted that the cabinet is provided with a heat dissipation structure for communicating the lower cold channel 40 with the lower hot channel 39, which is convenient for the lower cold channel 40, the lower hot channel 39, the upper hot channel 38 and the upper cold channel to communicate in turn to form a gas circulation loop, thus enabling a gas in the cold channel to enter the cabinet to cool other components therein.

In some embodiments, the liquid cooling cabinet 21 may be a single-phase liquid cooling unit, or a phase change liquid cooling unit and other liquid cooling units.

In some embodiments, the space above the cabinet is at least provided with two first sealing plates 15, i.e., the two first sealing plates 165 in the width direction. Certainly, one first sealing plate can be laid on the top of each of the computing cabinet 12 and the network cabinet 13, thus preventing cooling liquid from leaking into the computing cabinet 12 and the network cabinet 13 after the liquid cooling pipeline 36 is damaged, and the security is improved.

In some embodiments, an anti-static layer 8 is paved on the bottom of the lower enclosure 6.

In some embodiments, the cable trays 22 are internally provided with a network raceway 25, a weak current raceway 26 and a heavy current raceway 27. Second sealing plates 24 are arranged on both sides of the cable tray 22 in a width direction, and the second sealing plates 24 are configured to isolate the cable trays 22 from the upper hot channel 38 and the upper cold channel 23.

In some embodiments, the lower enclosure 6 has the same length and width as the upper enclosure 5.

In this embodiment, the whole data center prefabricated module has a regular shape.

In some embodiments, a constant-humidity unit 31 and a fresh air unit 32 are arranged in the space above the cable trays 22.

In some embodiments, each of four side surfaces of the upper enclosure 5 and the lower enclosure 6 is provided with a fire roller shutter 7, and each of the upper enclosure 5 and the lower enclosure 6 is provided with a sliding door 14 at least at one side surface in the length direction.

The fire roller shutter 7 in this embodiment may be manually controlled or automatically controlled by a control system. When the fire roller shutter is automatically controlled by the control system, a corresponding control logic and a sensor for fire detection need to be provided, such as a smoke sensor, or a temperature sensor. Then, in case of fire, the fire roller shutter 7 automatically descends to isolate a fire region. The sliding door 14 is provided to facilitate workers to enter an enclosure body from one end of the upper enclosure 5 and the lower enclosure 6 to carry out maintenance and other operations on the components.

In this embodiment, the design of fire protection in different zones is achieved. In case of sudden fire, the fire roller shutter 7 descends quickly to isolate the fire region, and a gas fire extinguishing system can extinguish the fire quickly, which can effectively reduce the risk loss of the modular data center 1.

In some embodiments, the sliding door 14 is provided with tracks extending in a vertical direction. When the fire roller shutter 7 transitions from an open state (i.e., a rolled-up state) to a closed state (i.e., a deployed state), when the fire roller shutter 7 slides down, a slider of the fire roller shutter 7 enters the track from the top of the track, and the track is configured to assist the fire roller shutter 7 to slide down vertically, thus improving the stability of the fire roller shutter in the sliding process and the closed state.

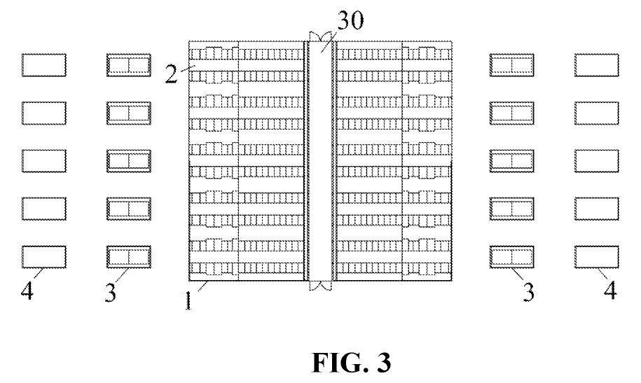

It needs to be noted that in a normal state, the sliding door 14 is always in the closed state, that is, in the normal state, all tracks are in their original positions to provide sliding support for the fire roller shutter 7, and the sliding door 14 can be opened only when the maintenance personnel enter the enclosure body. Therefore, in the normal state, the sliding door 14 can provide sliding support for the fire roller shutter 7. In addition, in the normal state, the fire roller shutter 7 in the modular data center shown in FIG. 3 is always in the open state, and there is no need of the support of the track on the sliding door 14. As for the fire roller shutter 7 at the outermost long side surface, as the fire roller shutter 7 at the outermost long side surface is usually closed, the track is not fixed to the sliding door, but to a frame of the sliding door, and a track corresponding to the fire roller shutter 7 at a short side surface is still arranged on the sliding door 14. However, as the fire roller shutter 7 is usually located outside the sliding door 14, it is necessary to open the fire roller shutter 7 before opening the sliding door 14 when entering the enclosure. Therefore, the purpose of arranging the track of the fire roller shutter 7 on the sliding door can be achieved.

In this embodiment, there is no need to additionally provide an upright post to install the track, which greatly reduces the number of upright posts in the data center, increases the activity space of staff or maintenance personnel, and facilitates the development of the work.

The sliding door in this embodiment may be replaced with a flush door.

In some embodiments, the lower enclosure 6 is internally provided with a partition 9 which is arranged in a direction perpendicular to the length direction of the lower enclosure 6 and configured to divide an internal space of the lower enclosure 6 into a computer room 10 and a support area 11. Multiple computing cabinets 12 and network cabinets 13 are arranged in the computer room 10; and the distribution cabinet, the UPS cabinet 17, the storage battery cabinet 18, the fire protection cabinet 20 and the liquid cooling cabinet 21 are arranged in the support area.

In this embodiment, one partition 19 is adopted to isolate the computer room 10 from the support area 11.

Preferably, a position of the partition 9 is adjustable, and then the lengths of the computer room 10 and the support area 11 are adjusted as required. In this embodiment, the partition 9 can be flexibly moved according to the demand of the computing power capacity to adjust spatial partitions occupied by the computer room 10 and the support area 11.

In some embodiments, a grating 35 is fixedly arranged at the bottom of the upper cold channel 23.

The grating in this embodiment can achieve air circulation, and can be used a channel for maintenance personnel, and the air-conditioning maintenance personnel can maintain the air-conditioning terminal 28 without entering the computer room 10.

In some embodiments, multiple fans are sequentially arranged at the bottom of the upper cold channel 23 in a length direction to form a fan set 29, and the fan set 29 is located below the grating 35. Multiple air-conditioning terminals 28 are sequentially arranged above the cable trays 22 in a length direction, one side of the air-conditioning terminal 28 is provided with an air valve 34, and one air conditioning terminal 28 corresponds to one air valve. In this embodiment, the air conditioning terminal 28 and the fan set 29 are independently arranged, respectively, and thus the air-condition terminals 28 and the fan set 2 are out of one-to-one correspondence. When a refrigeration main engine or an evaporator (air conditioning terminal 28) fails, the corresponding air valve 34 is closed to avoid air mixing, and the fan set 29 operates normally to extract the cold air in the upper cold channel 23 without affecting cold energy transmission and distribution. When a fan in the fan set 29 fails, only the faulty fan needs to be handled without affecting the cold energy transmission and distribution, which significantly improves the system redundancy.

In some embodiments, a top plate is fixedly arranged at the top of the upper enclosure 5, a bottom plate is detachably arranged at the bottom of the upper enclosure 5, a top plate is detachably arranged at the top of the lower enclosure 6, and a bottom plate is fixedly arranged at the bottom of the lower enclosure 6. First upright posts 37 are fixedly arranged inside each of the upper enclosure 5 and the lower enclosure 6, and second upright posts 33 are detachably arranged at four side edges of the upper enclosure 5 and the lower enclosure 6, respectively.

In this embodiment, after the prefabrication of the upper enclosure 5 and the lower enclosure 6 is completed, the structure includes the bottom plate of the upper enclosure 5, the top plate of the lower enclosure 6 and the four second upright posts 33. That is, during transportation, the second upright post 33, the bottom plate and the top plate plays a role in protecting the components inside the enclosure, such as the cabinet, the air conditioning terminal 28 and other structures. It may be understood that in the transportation state, the four fire roller shutters 7 are all in the closed state, that is, the four fire roller shutters 7 are served as four sidewalls of the upper enclosure 5 and the lower enclosure 6, and no additional side plates are required.

After being transported to the site, during assembly, as shown in FIG. 3, the four second upright posts 33 as well as the bottom plate of the upper enclosure 5 and the top plate of the lower enclosure 6 can be dismounted to serve as building materials for the middle corridor 30 to be assembled.

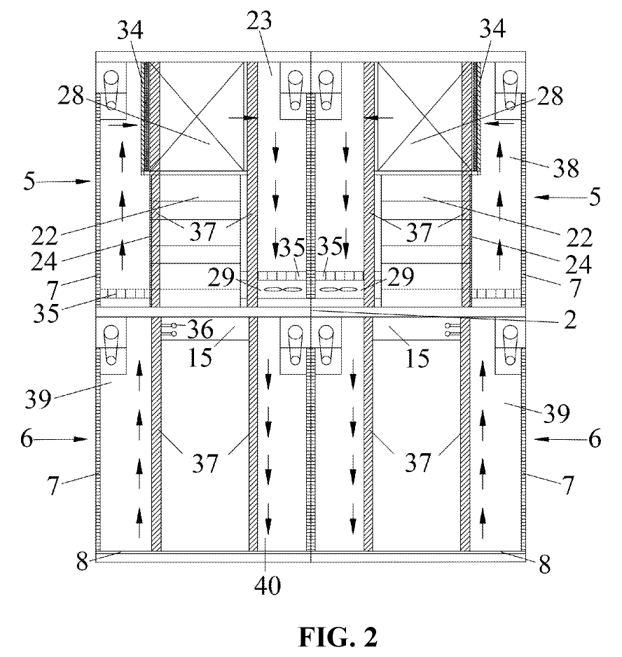

As shown in FIG. 2, the first upright posts 37 in the upper enclosure 5 are fixedly connected with the top plate of the upper enclosure 5, the first upright posts 37 in the lower enclosure 6 are fixedly connected with the bottom plate of the lower enclosure 6, and each of the components in the upper enclosure 5 and the lower enclosure 6, when needing to be fixed, can be fixedly connected with the top plate, the bottom plate or the first upright post 37. For example, the first upright posts are arranged on both sides of the cable tray in the width direction, the cable trays are fixedly connected with the first upright posts 37, the constant-humidity unit 31, the fresh air unit 32 and the air conditioning terminal 28 are directly or indirectly connected with the first upright post 37. The first upright posts 37 are also arranged on both sides of the cabinet, and the cabinet can be directly or indirectly fixedly connected with the bottom plate, or directly or indirectly fixedly connected with the first upright post 37.

### Embodiment II

An embodiment of the present disclosure further provides a data center prefabricated unit 2, including two data center prefabricated modules above. In an installation state, the two data center prefabricated modules are symmetrically arranged along a vertical plane parallel to the length direction of an upper enclosure 5.

In this embodiment, after assembly, fire roller shutters 7 located on adjacent sides of two upper enclosures 5 and fire roller shutters 7 located on both sides of two lower enclosures 6 can be opened, which can make the two data center prefabricated modules share the cold channel, increase the space of the cold channel, and further make the cold distribution in each module even and improve the refrigeration effect.

### Embodiment III

The present disclosure further provides a modular data center 1, including multiple data center prefabricated units 2 in the above embodiments, medium-voltage distribution boxes 3 and cooling outdoor units 4.

The modular data center provided by the present disclosure, after being assembled, can provide computing power by only connecting a cable, a refrigeration pipeline and a liquid cooling pipeline 36. In the modular data center 1, cold and hot channels are separated, an air conditioning terminal 28 is directly adjacent to a server to further improve an evaporation temperature. The fan set 29 can accurately deliver air to the server, thus achieving cabinet-level cooling.

The medium-voltage distribution box 3 is installed near the data center prefabricated unit 2, is internally provided with a medium-voltage distribution cabinet and a transformer, and is directly connected to a 10 KV medium-voltage power supply.

The cooling outdoor unit 4 may be one or a combination of more of a cooling tower, a cooling unit, a direct expansion air conditioning unit, a liquid cooling unit and a phase change liquid cooling unit.

In some embodiments, multiple data center prefabricated units 2 are provided, which are sequentially arranged in a width direction of a single data center prefabricated unit 2 to form a data center prefabricated unit 2 group.

In some embodiments, multiple data center prefabricated unit 2 groups are provided, which are sequentially arranged in the length direction of a single data center prefabricated unit, and a corridor 30 is arranged between two adjacent data center prefabricated unit 2 groups.

When the modular data center 1 is assembled by adopting the data center prefabricated module, the upright posts, the bottom plates and the top plates in the upper enclosure 5 and the lower enclosure 6 are dismounted, and then a data center prefabricated unit 2 is symmetrically assembled. The upright posts, the bottom and the top plates are assembled into the corridor 30 of the modular data center 1. After assembly, the fire roller shutters 7 in the modular data center 1 are all opened (i.e., rolled up to the top), and thus various modules can effectively share the cold channel and the hot channel.

In addition, after all the internal fire roller shutters 7 are opened, any two adjacent lower enclosures 6 and any two adjacent upper enclosures 5 can be in communication to form a space, which is convenient for the workers to carry out overhauling and maintenance work.

A modular data center 1 shown in FIG. 3 is composed of ten data center fabrication units 2.

Specific examples are used herein for illustration of the principles and embodiments of the present disclosure. The description of the embodiments is merely used to help illustrate the method and its core principles of the present disclosure. In addition, a person of ordinary skill in the art can make various modifications in terms of specific embodiments and scope of application in accordance with the teachings of the present disclosure. In conclusion, the content of this specification shall not be construed as a limitation to the present disclosure.

What is claimed is:

1. A data center prefabricated module, comprising:
an upper enclosure, wherein the upper enclosure is internally provided with cable trays extending in a length direction of the upper enclosure, an upper cold channel and an upper hot channel are respectively formed on both sides of each of the cable trays in a width direction, the upper cold channel communicates with the upper hot channel through a first space above each of the cable trays, an air conditioning terminal is arranged in the first space above each of the cable trays, and a pneumatic power source for driving gas to flow is arranged in the upper cold channel, the upper hot channel or the first space above each of the cable trays;
a lower enclosure, wherein a plurality of cabinets are sequentially arranged in the lower enclosure in a length direction of the lower enclosure, the cabinets comprising: a computing cabinet, a network cabinet, a distribution cabinet, a UPS (uninterrupted power supply) cabinet, a storage battery cabinet, a fire protection cabinet and a liquid cooling cabinet; a liquid cooling pipeline is arranged in a second space above the cabinets, the liquid cooling pipeline communicates with the computing cabinet as well as a liquid cooling channel in the network cabinet, first sealing plates are arranged on both sides of the second space above the cabinet in a width direction, respectively, and the cabinets and the first sealing plates divide a remaining space of the lower enclosure into a lower cold channel and a lower hot channel; and
in an installation state, the upper enclosure is stacked on the lower enclosure, the lower cold channel communicates with the upper cold channel, and the lower hot channel communicates with the upper hot channel.

2. The data center prefabricated module according to claim 1, wherein a length and a width of the lower enclosure are the same as a length and a width of the upper enclosure.

3. The data center prefabricated module according to claim 1, wherein each of four side surfaces of the upper enclosure and four side surfaces of the lower enclosure is provided with a fire roller shutter, and each of the upper enclosure and the lower enclosure is provided with a sliding door at one side surface in the length direction.

4. The data center prefabricated module according to claim 1, wherein the lower enclosure is internally provided with a partition which is arranged in a direction perpendicular to the length direction of the lower enclosure and which divides an internal space of the lower enclosure into a computer room and a support area, and a plurality of computing cabinets and network cabinets are arranged in the computer room; and the distribution cabinet, the UPS cabinet, the storage battery cabinet, the fire protection cabinet and the liquid cooling cabinet are arranged in the support area.

5. The data center prefabricated module according to claim 1, wherein a grating is fixedly arranged at a bottom of the upper cold channel.

6. The data center prefabricated module according to claim 1, wherein a first top plate is fixedly arranged at a top of the upper enclosure, a first bottom plate is detachably arranged at a bottom of the upper enclosure, a second top plate is detachably arranged at a top of the lower enclosure, and a second bottom plate is fixedly arranged at a bottom of the lower enclosure; first upright posts are fixedly arranged inside each of the upper enclosure and the lower enclosure, and second upright posts are detachably arranged at four side edges of the upper enclosure and the lower enclosure, respectively.

7. A data center prefabricated unit, comprising two data center prefabricated modules according to claim 1, wherein in the installation state, the two data center prefabricated modules are symmetrically arranged along a vertical plane parallel to the length direction of the upper enclosure.

8. A modular data center, comprising a plurality of data center prefabricated units according to claim 7, medium-voltage distribution boxes and cooling outdoor units.

9. The modular data center according to claim 8, wherein the plurality of data center prefabricated units are sequentially arranged in a width direction of a single data center prefabricated unit to form a data center prefabricated unit group.

10. The modular data center according to claim 9, wherein a plurality of data center prefabricated unit groups are provided, which are sequentially arranged in a length direction of the single data center prefabricated unit, and a corridor is arranged between two adjacent data center prefabricated unit groups of the plurality of data center prefabricated unit groups.
